(19) United States
(12) Patent Application Publication
(10) Pub. No.: US 2014/0291831 A1
(43) Pub. Date: Oct. 2, 2014

(54) SEMICONDUCTOR DEVICE AND MANUFACTURING METHOD FOR SEMICONDUCTOR DEVICE

(71) Applicant: Toru Tanaka, Nagoya-shi (JP)

(72) Inventor: Toru Tanaka, Nagoya-shi (JP)

(73) Assignee: TOYOTA JIDOSHA KABUSHIKI KAISHA, Toyota-shi (JP)

(21) Appl. No.: 14/226,009

(22) Filed: Mar. 26, 2014

(30) Foreign Application Priority Data
Mar. 28, 2013 (JP) 2013-069828

(51) Int. Cl. H01L 23/367; H01L 23/00

(52) U.S. Cl. CPC H01L 23/367; H01L 23/564
USPC 257/712; 438/122

(57) ABSTRACT

A semiconductor device includes a metallic plate, a bonding layer, a semiconductor chip, and a resin molding. The semiconductor chip is fixed to the metallic plate with the bonding layer. The resin molding is in contact with the metallic plate, and covers the semiconductor chip. In the semiconductor device, a dent is provided in the metallic plate so that the dent is located next to an edge of a fillet of the bonding layer, in a plan view of the metallic plate.

### INCORPORATION BY REFERENCE

The disclosure of Japanese Patent Application No. 2013-069828 filed on Mar. 28, 2013 including the specification, drawings and abstract is incorporated herein by reference in its entirety.

### BACKGROUND OF THE INVENTION

1. Field of the Invention

The invention relates to a semiconductor device in which a semiconductor chip is covered by a resin molding, and a manufacturing method for the semiconductor device.

2. Description of Related Art

There is known a semiconductor device, in which a semiconductor chip is soldered onto a metallic plate and covered by a resin molding. A resin body that covers a semiconductor chip will be herein referred to as a resin molding or a resin package. A metallic plate can be a lead frame, or a heat sink that releases heat of the semiconductor chip to outside a resin package. The expressions “to seal” or “to package” are sometimes used instead of the expression “to cover with a molding”.

In many cases, a resin molding (a resin package) is formed by injection molding. In order to enhance bondability between a resin molding that covers a semiconductor chip, and a metallic plate or the semiconductor chip, a primer (a base material) is sometimes placed between the resin molding and the metallic plate (or the semiconductor chip) (for example, Japanese Patent Application Publication No. 2011-165871 A (JP 2011-165871 A)).

Japanese Patent Application Publication No. 2010-258483 A (JP 2010-258483 A) is given as a document that describes a technology with a similar structure to a structure of a semiconductor device described herein. The semiconductor device described in JP 2010-258483 A is as follows. A semiconductor chip is fixed to a substrate, and the semiconductor chip is covered by a resin molding. A through hole is provided in the substrate, and an inner surface of the through hole is plated. The resin molding that covers the semiconductor chip is also filled in the through hole. An objective of the technology in JP 2010-258483 A is to discharge moisture inside the resin molding to outside. Since bondability between plating and resin is not high, a boundary between the plating and the resin becomes a path for moisture to be discharged outside the resin molding.

When a primer layer, which is formed on a surface of the metallic plate or the semiconductor chip, is thick, there is a possibility that only a surface layer of the primer layer is hardened, and inside of the primer layer is not hardened. Therefore, it is preferred that the primer layer has a thin and even film thickness. To be specific, the film thickness of the primer layer is preferably 20 microns or smaller, and the film thickness of 10 microns or smaller is more preferred.

### SUMMARY OF THE INVENTION

The above-stated values for the film thickness of the primer layer is 10 times smaller than a thickness of a solder layer between the semiconductor chip and the metallic plate (normally about 150 microns). The primer is applied not only on the metallic plate but also on an exposed portion of the semiconductor chip and an exposed portion of the solder layer. As widely known, a side end area of a solder layer that bonds two objects (for example, the semiconductor chip and the metallic plate) together is called a fillet. In a semiconductor device, an area of the metallic plate is larger than an area of the semiconductor chip. Therefore, the fillet of the solder layer between the semiconductor chip and the metallic plate spreads from the semiconductor chip side toward the metallic plate. Simply applying the primer causes an increase in the thickness of the primer layer in a boundary between the fillet and the metallic plate (in other words, an edge of the fillet). Then, in the completed semiconductor device, inside of a thick portion of the primer layer may not be solidified sufficiently. Thus, the resin molding is separated easily.

The present invention provides a semiconductor device, in which an increase in a film thickness of a primer layer near a fillet is prevented, and separation hardly happens. The present invention also provides a manufacturing method for the semiconductor device.

A semiconductor device according to a first aspect of the present invention includes a metallic plate, a bonding layer, a semiconductor chip, and a resin molding. The metallic plate has a dent and is fixed to the semiconductor chip with the bonding layer located between the semiconductor chip and the metallic plate. The semiconductor chip is covered with the resin molding. The resin molding is bonded to the metallic plate. The dent is located next to an edge of a fillet of the bonding layer, in a plan view of the metallic plate.

A manufacturing method for a semiconductor device according to a second aspect of the present invention includes: providing a dent in a metallic plate; and bonding a semiconductor chip to the metallic plate with a bonding layer after inserting a plug into the dent. The bonding layer is located between the semiconductor chip and the metallic plate. The dent is located next to an edge of a fillet of the bonding layer, in a plan view of the metallic plate.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a perspective view of a semiconductor device according to an embodiment of the present invention;

FIG. 2 is an exploded perspective view of the semiconductor device according to a first embodiment of the present invention (a resin molding is not shown);

FIG. 3 is a sectional view taken along the line III-III in FIG. 1;

FIG. 4 is an enlarged view of a region surrounded by a broken line IV in FIG. 3;

FIG. 5 is a sectional view of a semiconductor device without a through hole, corresponding to the related art;

FIG. 6 is a plan view of the semiconductor device according to a first embodiment of the present invention (a resin molding is not shown);

FIG. 7 is a plan view of a semiconductor device according to a second embodiment of the present invention (a resin molding is not shown);

FIG. 8A is a plan view of a semiconductor device according to a third embodiment of the present invention, and FIG. 8B is a sectional view taken along the line B-B in FIG. 8A;

FIG. 9 is an enlarged view of a region surrounded by a broken line IX in FIG. 8B;

FIG. 10 is a view explaining a manufacturing method for the semiconductor device according to an embodiment of the present invention;

FIG. 11 is a table showing conditions for prototypes of the present invention; and

FIG. 12 is a table showing test results of the prototypes of the present invention.

### DETAILED DESCRIPTION OF EMBODIMENTS

First of all, an outline of an embodiment of the present invention will be explained. The embodiment of the present invention is a semiconductor device in which semiconductor chips are fixed to a metallic plate with a bonding layer, and the semiconductor chips are covered by a resin molding. The resin molding is bonded to the metallic plate. A structure of the metallic plate may be such that one surface of the metallic plate is attached firmly to the resin molding, and the other surface of the metallic plate is exposed, and, the metallic plate is entirely sealed by the resin molding. An embodiment of the structure, in which the other surface of the metallic plate is exposed, may be regarded as a structure in which the metallic plate is a heat sink. An embodiment of the structure, in which the metallic plate is entirely sealed by the resin molding, is a structure in which the metallic plate is a lead frame. Although the resin molding is in contact with the metallic plate, a primer (a coating agent that enhances bonding between the metallic plate and the resin) may be placed between the resin molding and the metallic plate. A typical example of the bonding layer is a solder layer. The bonding layer may also be an adhesive layer. In order to facilitate understanding, the explanation will continue, assuming that the bonding layer is the solder layer.

Immediately after the primer is applied, a state of the primer layer is observed before covering the primer layer with the resin molding. Then, an excessive primer flows along side surfaces of semiconductor chips (surfaces perpendicularly arranged to a surface of the metallic plate), and a surface of a fillet. The excessive primer is then accumulated in a boundary between the fillet and the metallic plate (in other words, an edge of the fillet). It was found that the accumulation of the primer is a cause of a large film thickness of the primer layer. Therefore, in the embodiment of the present invention, a dent is provided adjacent to the edge of the fillet in a plan view of the metallic plate of the semiconductor device. By employing such a structure, the excessive primer that has been accumulated in the edge of the fillet falls into the dent. Therefore, an increase in the film thickness of the primer layer at the edge of the fillet is prevented. A dent that passes through the metallic plate is more favorable. The excessive primer falls down from the metallic plate, and the dent is not overflown with the primer. It is preferred that the dent circles around the semiconductor chip along the edge of the fillet. However, the dent may be provided only in corner portions of the fillet that has a generally rectangular shape in a plan view. Since the primer is accumulated in the corner portions of the fillet easily, there is an effect simply by providing the dent adjacent to the corner portions, even if the dent does not circle around the semiconductor chip. A several dents may also be provided along the edge of the fillet. In a case where the through hole, which passes through the metallic plate, is provided as the dent, it is impossible to provide the through hole that surrounds the semiconductor chip. Therefore, it is preferable that some through holes are provided in the corner portions or along the edge of the fillet, as stated earlier.

In observation in the order of a size of the semiconductor chip (the millimeter order), it can be considered that the dent is located next to the edge of the fillet. When the thickness of the primer layer is observed in the order (the 1 to 10 micron order) that is smaller than the order of the size of the semiconductor chip, there is a given distance between the dent and the edge of the fillet. Although depending on viscosity of the primer, it is preferred that the distance is equal to or less than twice an average thickness of the primer applied on the metallic plate before the resin molding is formed. Unless the dent is so close to the edge of the fillet as stated above, the excessive primer accumulated in the edge of the fillet does not flow into the dent sufficiently. Because the average thickness of the primer layer is about 20 microns or less, an example of a specific numerical value of the distance between the dent and the edge of the fillet is 40 microns or less, or, more preferably, 20 microns or less. Although depending on viscosity of the primer, a diameter of the dent is about 100 microns.

In the semiconductor device described in JP 2010-258483 A introduced earlier, the location of the through hole provided in the substrate is not limited, and is unrelated to the location of the edge of the fillet. It should be noted that, in the technology described in JP 2010-258483 A, the through hole is provided in the substrate in order to remove moisture existing inside the resin molding, and there is no limit on the location of the through hole (the dent).

A typical example of the primer is a thermosetting polyimide resin. For this type of resin, N-methyl-2-Pyrrolidone (NMP) is used as a solvent. A surface layer of a thermosetting polyimide primer, which is diluted with NMP, is solidified faster than inside, which easily results in a state where a surface layer of a portion with a large film thickness is hardened, but inside is not solidified. The embodiment of the present invention is preferably applied when a primer, whose main component is a thermosetting polyimide resin, is used.

In the embodiment of the present invention, a manufacturing method is used, which is preferably employed for the above-mentioned semiconductor device having the dent. As stated earlier, the dent is located next to the edge of the fillet. A work is easily done when the dent is provided in the metallic plate prior to soldering. In this case, if soldering is performed while the dent is exposed, melted solder could flow into the dent. Therefore, in the embodiment of the present invention, a plug is inserted into the dent before soldering the semiconductor chip. More preferably, the plug is used effectively by using a part of the plug exposed from the dent in order to decide the position of the semiconductor chip. The exposed part of the plug may be used to position the semiconductor chip directly, or a jig for positioning the semiconductor chip may be fixed to the exposed part of the plug.

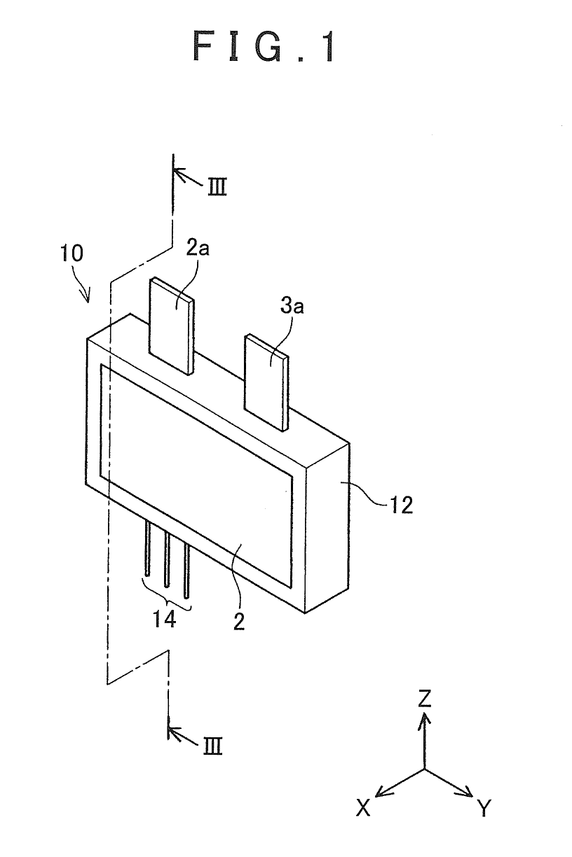

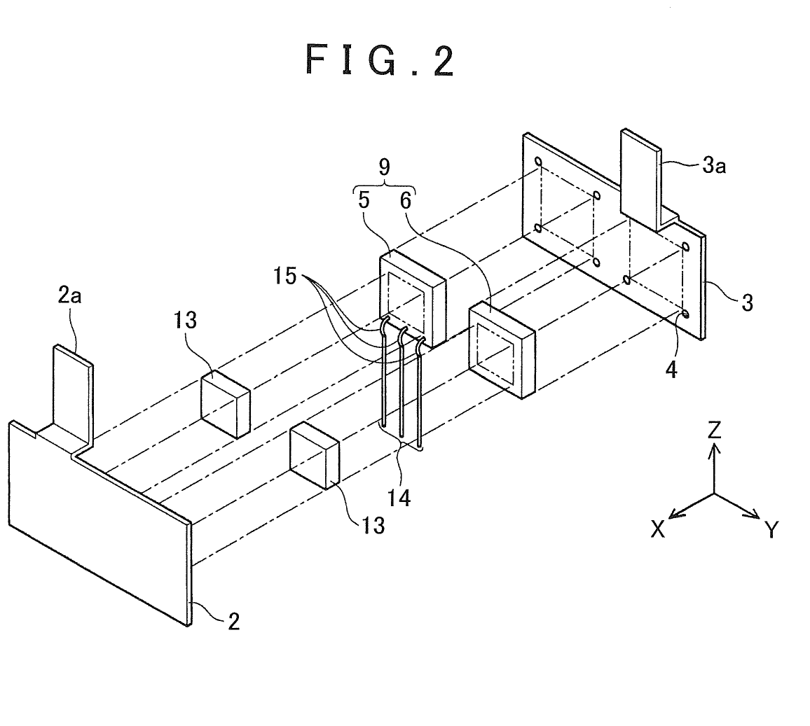

A semiconductor device 10 according to a first embodiment of the present invention will be explained with reference to the drawings. FIG. 1 shows a perspective view of the semiconductor device 10. FIG. 2 shows an exploded perspective view of the semiconductor device 10. However, a resin molding 12 is not shown in FIG. 2 in order to facilitate understanding. The semiconductor device 10 is a device in which a transistor chip 5 and a diode chip 6 are covered with a resin molding. The transistor chip 5 is, more specifically, an insulated gate bipolar transistor (IGBT). Herein below, in some cases, the transistor chip 5 and the diode chip 6 will be collectively referred to as semiconductor chips 9.

In the semiconductor device 10, two semiconductor chips 9 are covered with the resin molding 12 between two metallic plates 2, 3. The two metallic plates 2, 3 serve as electrode plates of anti-parallel circuits for the transistor chip 5 and the diode chip 6, respectively, and also serve as heat sinks that release heat of the semiconductor chips 9 to outside of the resin molding 12. A shown in FIG. 1, one surfaces of the metallic plates 2, 3 are exposed on the surfaces of the resin molding 12. For convenience of explanation, the exposed sides of the metallic plates 2, 3 will be referred to as outside surfaces, and the sides of the metallic plates 2, 3, which are in contact with the resin molding 12, will be referred to as inside surfaces.

As shown in FIG. 2, the transistor chip 5 is a flat plate. Although not shown, an emitter electrode is exposed on one surface of the transistor chip 5, and a collector electrode and a gate electrode are exposed on the other surface of the transistor chip 5. The diode chip 6 is also a flat plate. An anode electrode is exposed on one surface of the diode chip 6, and a cathode electrode is exposed on the other surface of the diode chip 6.

The emitter electrode side of the transistor chip 5, and the anode electrode side of the diode chip 6 are fixed to the inside surface of the metallic plate 3 with a solder. Spacers 13 are fixed to the collector electrode of the transistor chip 5, and the cathode electrode of the diode chip 6, respectively, with a solder. Surfaces of the spacers 13, which are on the opposite sides of the surfaces of the spacers 13 fixed to the transistor chip 5 and the diode chip 6, are fixed to the inside surface of the metallic plate 2 with a solder. Both the solder and the spacers 13 are electrically conductive. Thus, each of the electrodes (the emitter electrode and the collector electrode) of the transistor chip 5, and each of the electrodes (the anode electrode and the cathode electrode) of the diode chip 6 are electrically conducted with the metallic plate 2 or the metallic plate 3 via the solder and the spacers. This way, terminals 2a, 3a extending above the resin molding 12 from the metallic plates 2, 3 serve as electrodes of anti-parallel circuits for the transistor chip 5 and the diode chip 6. Copper is suitable for the spacers 13 because copper has low internal resistance and high thermal conductivity.

Gate electrodes (not shown) exposed on a part of the surface of the transistor chip 5 are connected with gate terminals 14 via bonding wires 15. The gate terminals 14 extend below the resin molding 12 (see FIG. 1). The bonding wire 15 is a metal wire made of, for example, aluminum, with a diameter of about 0.15 mm. The transistor chip 5, the diode chip 6, the bonding wires 15, and distal ends of the gate terminals 14 (on the side connected to the bonding wires 15), which are sandwiched between the two metallic plates 2, 3, are covered (sealed) with the resin molding 12.

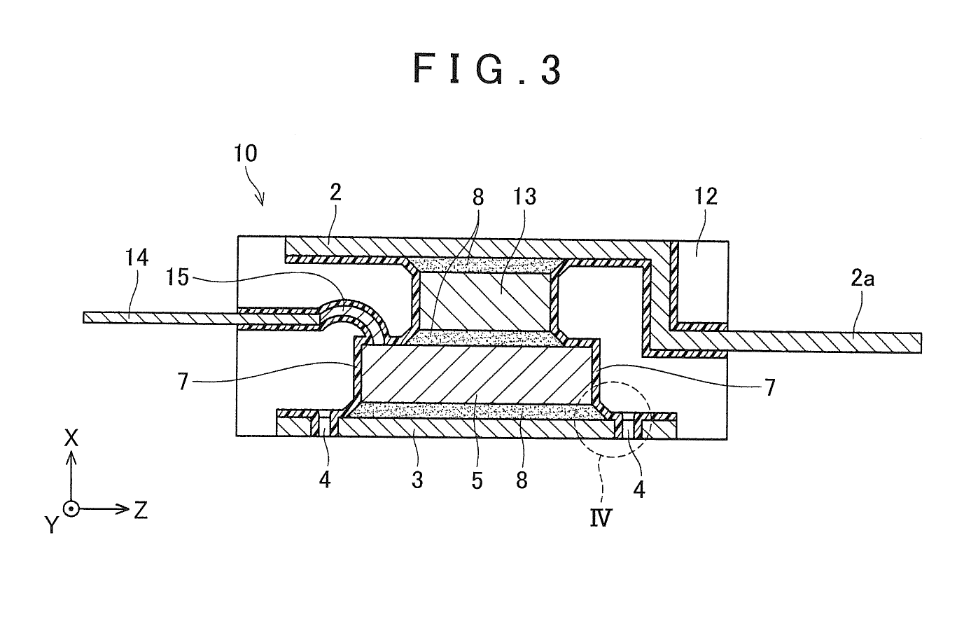

Eight through holes 4 are provided in the metallic plate 3, to which the semiconductor chips are fixed with the solder. The through holes will be explained with reference to FIG. 3 to FIG. 5. FIG. 3 is a sectional view taken along the line III-III in FIG. 1. In FIG. 3, hatching that represents a section is not shown in the section of the resin molding 12 in order to facilitate understanding. A relation between the transistor chip 5 and the through holes 4 will be explained, and the diode chip 6 and the through holes 4 have the same relation.

The transistor chip 5 is fixed to the metallic plate 3 with the solder 8. The layer-shaped solder 8 is present between the spacer 13 and the transistor chip 5, and between the spacer 13 and the metallic plate 2. Since the solder 8 is shaped like a layer, the solder 8 will be referred to as the solder layer 8 herein below.

The semiconductor chips 9, the bonding wires 15, the distal ends of the gate terminals 14 (on the side connected to the bonding wires 15), which are sandwiched between the two metallic plates 2, 3, are covered (sealed) with a primer (a primer layer 7). The primer layer 7 is covered with the resin molding 12. The primer is a base material that is applied in order to enhance bondability between the resin molding 12 and the metallic plates 2, 3 that are hard, and the semiconductor chips 9. Typically, epoxy resin is used for the resin molding, and a thermosetting polyimide resin is used for the primer. Before the resin molding 12 is formed, an entire assembly including the semiconductor chips 9 soldered to the metallic plates 2, 3 is immersed in a solution of the primer, thereby forming the primer layer 7. The assembly, in which the primer layer 7 is formed, is put in a mold, and injection molding of melted epoxy resin is performed, thereby forming the resin molding 12. A metal filler is sometimes mixed into the epoxy resin used for the resin molding 12 in order to increase stiffness. In this case, bondability between the resin molding 12 and the metallic plate and so on is reduced further, and the primer layer 7 is thus required. A thickness of the primer layer 7 is about 10 to 20 microns, which is very thin. It should be noted, however, that the thickness of the primer layer 7 is deformed in FIG. 3.

In the sectional view in FIG. 3, the through hole 4 provided in the metallic plate 3 is located in a boundary between the fillet of the solder layer 8 and the metallic plate 3. As clearly shown in FIG. 1, the through holes 4 are provided at positions that correspond to corner portions of the transistor chip 5 in a plan view of the transistor chip 5.

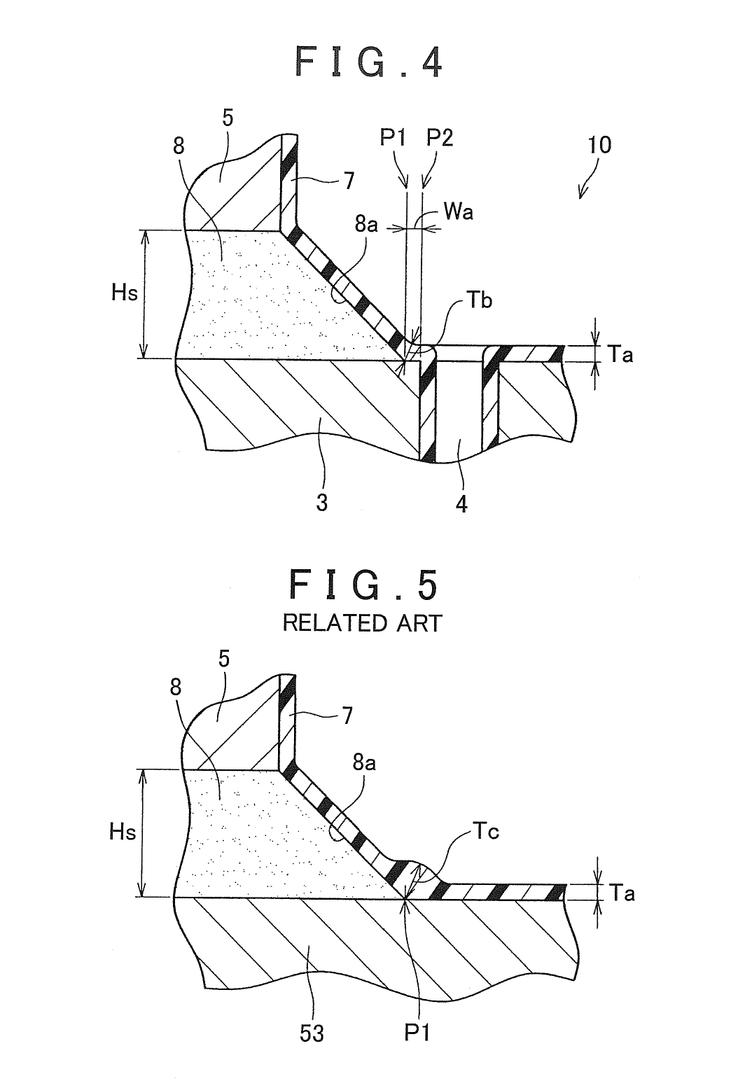

FIG. 4 shows an enlarged view of a region shown by the symbol IV in FIG. 3. A portion of the solder layer 8, which protrudes between the transistor chip 5 and the metallic plate 3, correspond to a fillet 8a. The primer layer 7 continues from a side surface of the transistor chip 5 to a surface of the fillet 8a. Further, the primer layer 7 continues from a boundary between an outer edge of the fillet 8a and the metallic plate 3 (the boundary will be referred to as an edge of the fillet 8a) to an inner side surface of the through hole 4. A thickness Hs of the solder layer 8 is generally 150 microns, and an average thickness Ta of the primer layer 7 is generally 10 microns.

Macroscopically, the edge of the fillet 8a and the through hole 4 are continuous, and the thickness of the primer layer 7 is almost constant on the surface of the fillet 8a, the inner side surface of the through hole 4, and the surface of the metallic plate 3. The thickness of the primer layer 7 is denoted by the symbol Ta in the drawing. Also, the thickness Tb of the primer layer 7 at the edge of the fillet 8a is generally equal to the thickness Ta of the primer layer 7 on the surface of the metallic plate 3. The thickness Ta is regarded as an average thickness of the primer layer 7.

Microscopically, there is a distance Wa between the edge of the fillet 8a (a spot denoted by the symbol P1 in FIG. 4) and an opening edge of the through hole 4 (a spot denoted by the symbol P2 in FIG. 4). In this embodiment, the distance Wa is equal to the average thickness Ta of the fillet. As stated earlier, the assembly before the resin molding 12 is formed is immersed into a solution of the primer, thereby forming the primer layer 7. Once the assembly is drawn up from the solution of the primer, an excessive primer (before solidified) in a liquid state attached to the side surface of the transistor chip 5 and the surface of the fillet 8a falls to and is accumulated at the edge of the fillet 8a. The excessive primer in the liquid state, which has temporarily been accumulated, flows into the through hole 4. The through hole 4 is located next to the edge of the fillet 8a macroscopically, and is separated from the edge of the fillet 8a by the distance Wa microscopically. Therefore, an increase in the thickness Tb of the primer layer 7 is prevented even at the edge of the fillet 8a.

For comparison, FIG. 5 shows a sectional view corresponding to FIG. 4, and shows a sectional view of a semiconductor device according to the related art, in which there is no through hole 4. When there is no through hole, an excessive primer accumulated at an edge P1 of a fillet 8a has nowhere to go, and is thus solidified in that spot. As a result, a thickness Tc of the primer layer 7 in the edge P1 of the fillet 8a becomes larger than an average thickness Ta.

As shown in FIG. 3 and FIG. 4, the excessive primer in the liquid state, which has been accumulated temporarily at the edge P1 of the fillet 8a, flows into the through hole 4. Therefore, the thickness of the primer layer 7 becomes equal to the average thickness Ta of the primer layer 7 at the edge P1 of the fillet 8a. When the thickness of the primer layer 7 is large, it is probable that only a surface is solidified, and inside is not solidified. However, the through hole 4 prevents an increase in the thickness of the primer at the edge P1 of the fillet 8a.

As clearly shown in FIG. 4, in order for the thickness of the primer layer 7 at the edge P1 of the fillet 8a to be equal to the average thickness Ta, it is preferred that, microscopically, the distance Wa between the edge P1 of the fillet 8a and the opening edge P2 of the through hole 4 is equal to the average thickness Ta of the primer layer 7. In this case, it should be noted that one is able to recognize that, macroscopically, the through hole 4 is located next to the edge of the fillet 8a. Although depending on fluidity of the melted primer, the distance Wa between the edge P1 of the fillet 8a and the opening edge P2 of the through hole 4 is up to twice the average thickness Ta of the primer layer 7, in order for the primer to flow into the through hole 4 without being accumulated at the edge of the fillet 8a. To be specific, since the preferred average thickness Ta of the primer layer 7 is between about 10 and 20 microns, the distance Wa between the edge P1 of the fillet 8a and the opening edge P2 of the through hole 4 is about 20 to 40 microns. The diameter of the through hole 4 may be any dimension as long as the through hole 4 is not clogged with the primer in the liquid state (the primer before solidified). Although depending on viscosity of the primer in the liquid state, the diameter of the through hole 4 may be approximately twice the average thickness Ta of the primer layer 7.

The explanation so far pertains to the transistor chip 5 and the through hole 4, but is also applicable to the diode chip 6 and the through hole 4.

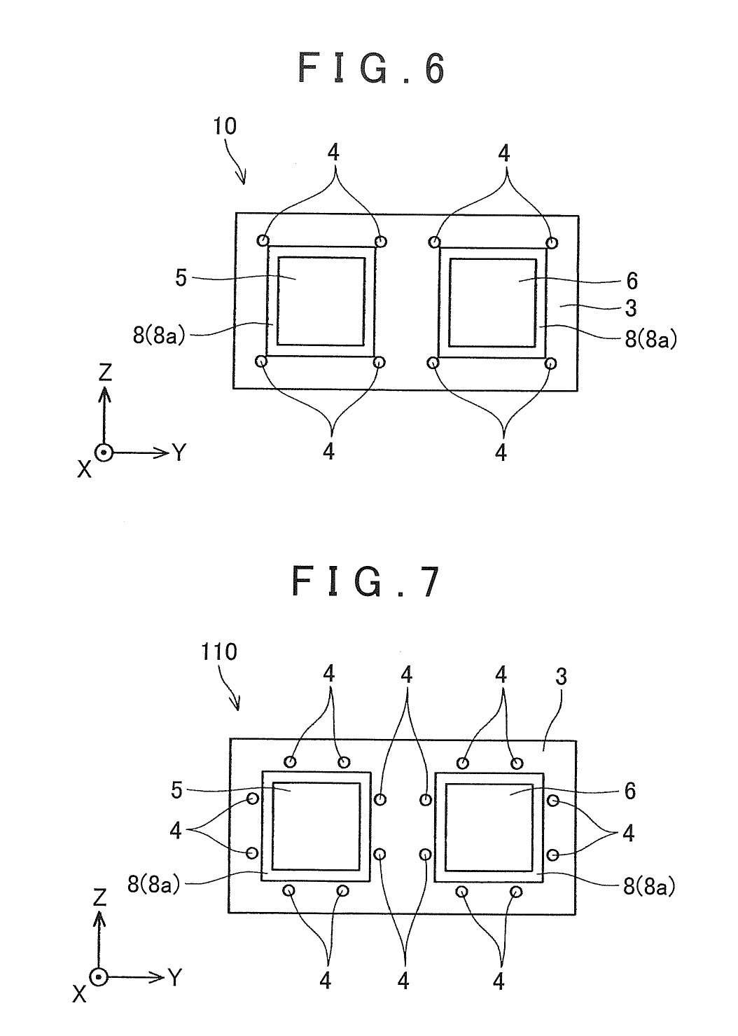

FIG. 6 shows a plan view of the semiconductor device 10. However, the metallic plate 2, the resin molding 12, the bonding wires 15, and the gate terminals 14 are not shown. As shown in FIG. 6, the through holes 4 are provided in the corner portions of the semiconductor chips (the transistor chip 5 and the diode chip 6) in a plan view of the semiconductor device 10. To be more precise, the through holes 4 are formed at corner portions of the fillets 8a of the solder layers 8, the fillets 8a being formed so as to surround the semiconductor chips. This is because, when the primer in the liquid state is applied, the primer is easily accumulated at the corner portions. Although it preferred that the through holes 4 are provided at the corner portions stated above, similar effects can be expected even when the through holes 4 are provided at different positions.

FIG. 7 shows a plan view of a semiconductor device 110 according to a second embodiment of the present invention. However, similarly to FIG. 6, a metallic plate 2, a resin molding 12 and so on are not shown. In the semiconductor device 110, through holes 4 are provided next to an outer periphery of a fillet 8a (an edge of the fillet) of a solder layer 8 that fixes semiconductor chips (a transistor chip 5 and a diode chip 6) to a metallic plate 3 in a plan view of the semiconductor device. In the semiconductor device 110 according to the second embodiment, positions and number of the through holes 4 are different from those in the semiconductor device 10 according to the first embodiment.

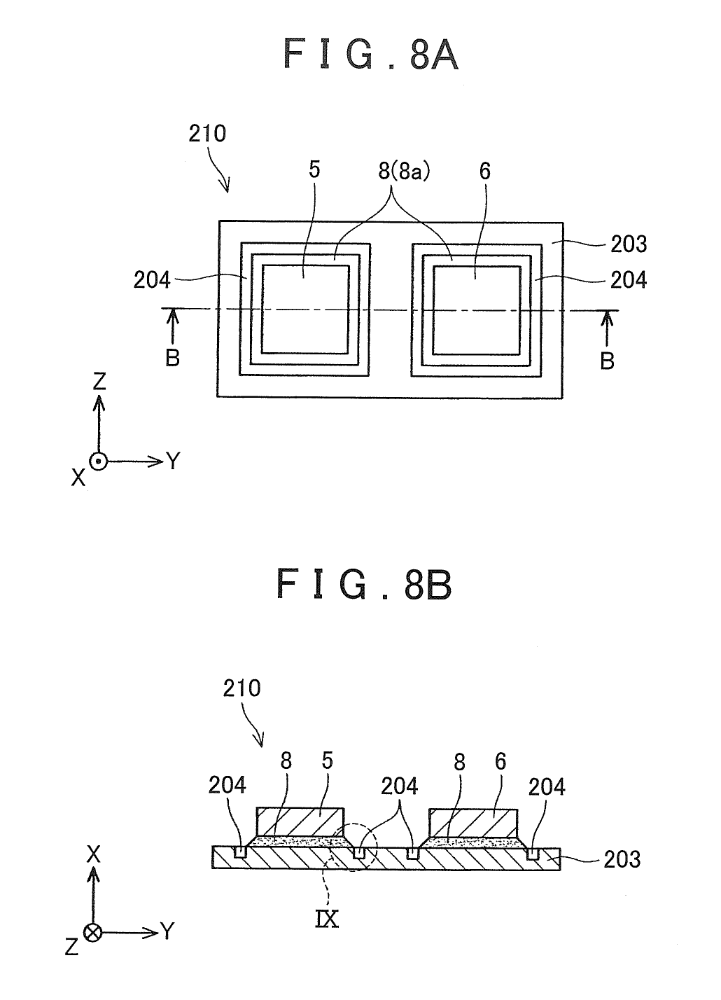

FIG. 8A and FIG. 8B show a semiconductor device 210 according to a third embodiment of the present invention. FIG. 8A is a plan view of the semiconductor device 210, and FIG. 8B is a sectional view taken along the line B-B in FIG. 8A. Similarly to FIG. 6, in FIG. 8A and FIG. 8B, a metallic plate 2, a resin molding 12 and so on are not shown. In the semiconductor device 210 according to the third embodiment, grooves 204 are provided in a metallic plate 203, instead of the through holes 4. The grooves 204 are respectively provided along outer edges of solder layers 8 (edges of the fillets 8a) to surround the solder layers 8 in a plan view of the semiconductor device 210. As shown in FIG. 8B, in a sectional view of the semiconductor device 210, the grooves 204 are located next to the edges of the fillets 8a of the solder layers 8.

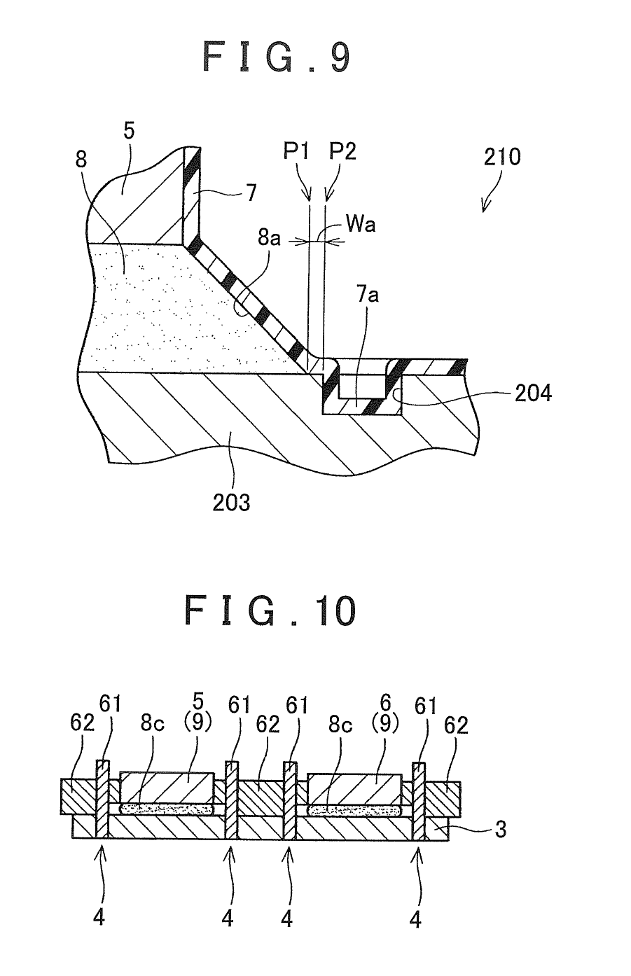

FIG. 9 shows an enlarged view of a region shown by a broken line IX in FIG. 8B. As evident from a comparison between the sectional view in FIG. 9 and the sectional view in FIG. 4, the only difference between the through holes 4 according to the first embodiment and the grooves 204 according to the third embodiment is whether or not to pass through a metallic plate. Unlike the through hole 4, a primer sump 7a is made inside the groove 204. However, unless the groove 204 is entirely filled with the primer, the groove 204 has the same advantages as the through hole 4. On the other hand, in the plan view (see FIG. 8A), since the grooves 204 are provided along the edges of the fillets 8a to surround fillets 8a, the semiconductor device 210 has an advantage that the thickness of the primer is not increased at any spot in the fillet 8a.

The first to third embodiments of the present invention have been explained so far. The semiconductor devices according to the first and second embodiments include the through holes in the metallic plate so that the through holes are located next to the edges of the fillets of the solder layers that fix the semiconductor chips to the metallic plate. The semiconductor device according to the third embodiment includes the grooves in the metallic plate along the edges of the fillets of the solder layers that fix the semiconductor chips to the metallic plate. Although it is preferred that the grooves are provided along the edges of the fillets to surround fillets 8a, similar effects are obtained only by providing the grooves, which do not surround the fillets, at some spots in the edges of the fillets. The through holes, the grooves that surround the fillets, and the grooves that do not surround the fillets, may be collectively referred to as “dents” provided in the metallic plate. In other words, in any of the semiconductor devices according to the embodiments of the present invention, the dents are provided in the metallic plate so that the dents are next to the edges of the fillets of the solder layers that fix the semiconductor chips to the metallic plate, in the plan view of the metallic plate to which the semiconductor chips are fixed.

Next, a manufacturing method for the semiconductor device will be explained based on an example of the semiconductor device 10 according to the first embodiment. As stated above, in the semiconductor device 10, the semiconductor chips 9 (the transistor chip 5 and the diode chip 6) are soldered to the metallic plate 3. Prior to the soldering, the through holes 4 are provided in the metallic plate 3. Then, while soldering, the semiconductor chips are positioned by using the through holes 4. FIG. 10 shows a sectional view for explaining positioning of the semiconductor chips. In FIG. 10, solder sheets 8c, having the same size as that of the semiconductor chips, are mounted on the metallic plate 3, and the semiconductor chips 9 are placed on the solder sheets 8c. In this stage, the semiconductor chips 9 are not fixed to the metallic plate 3. Positioning pins 61 are inserted into the through holes 4. The positioning pins 61 may be regarded as plugs according to the present invention. Parts of the positioning pins 61 extend above the through holes 4, and positioning blocks 62 are engaged with the parts of the positioning pins 61. Side surfaces of the positioning blocks 62 restrain the positions of both sides of the semiconductor chips 9, and the positions of the semiconductor chips 9 are thus defined. The positioning blocks 62 are made of a heat resisting material, and are resistant to melting temperature of the solder. A set of the metallic plate 3 and the semiconductor chips 9, with the positioning blocks 62 attached, are put in a high-temperature furnace. The solder is melted, and the semiconductor chips 9 are fixed to the metallic plate 3. Although the through holes 4 are located near the solder, melted solder does not flow into the through holes because the through holes 4 are closed by the positioning pin 61. After the solder is solidified again, the positioning pins 61 are removed together with the positioning blocks 62. This way, the through holes 4 are prevented from being filled with the solder while soldering. The positioning pins 61 contribute to not only protection of the through holes 4 but also positioning of the semiconductor chips 9.

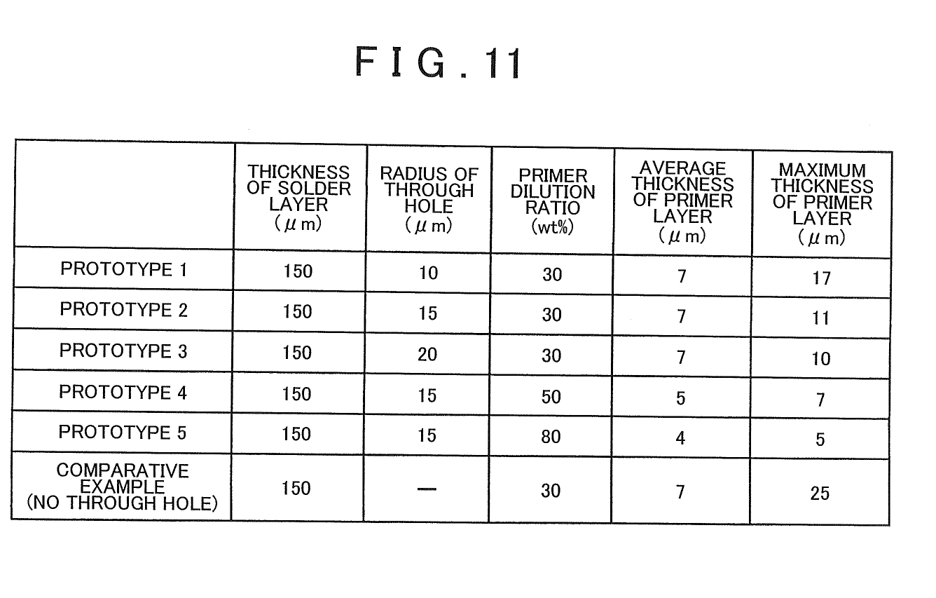

With regard to the foregoing first embodiment (in which the through holes are provided at four corners of the edge of the fillet in a plan view), prototypes were fabricated under different conditions such as a primer dilution ratio, and it was investigated whether or not separation happened. FIG. 11 shows conditions for five prototypes. An example without through holes (a comparative example) was also fabricated for comparison. Conditions common to all of the prototypes and comparative example are as follows. A lead frame, in which a nickel (Ni) was plated on oxygen free copper (Cu), was used for the metallic plate. A lead-free solder (Sn—0.7/Cu—0.06/Ni—0.03%), which is commercially available, was used for the solder. For the primer, liquid polyimide PIX8144 manufactured by HD MicroSystems, Ltd. was used, and NMP was used for dilution. For the resin molding, a commercially-available sealing material made of epoxy resin was used. For the semiconductor chips, chips based on silicone or silicon carbide were used. The “largest film thickness of a primer layer” in FIG. 11 is generated in the edge of the fillet near the through hole.

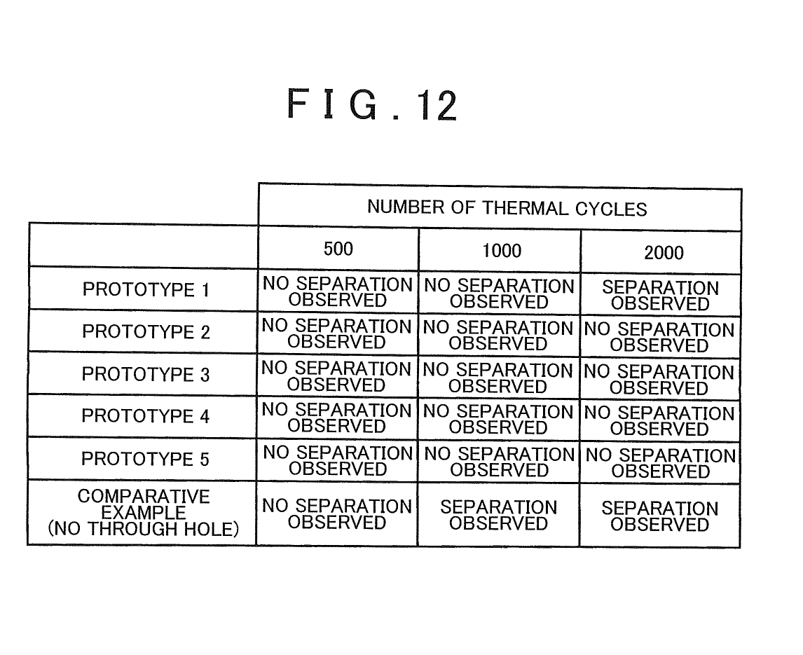

After a given number of thermal cycles are carried out on the prototypes and the comparative example, existence of separation was investigated. A thermal cycling test chamber manufactured by Espec Corp. was used for the thermal cycles, and, the conditions of holding for 15 minutes at 200 degrees centigrade, taking 15 minutes to reduce temperature to minus 40 degrees centigrade, holding for 15 minutes at minus 40 degrees centigrade, and taking 15 minutes to increase temperature to 200 degrees centigrade, was one cycle. Also, a gas phase method was used. Existence of separation was evaluated by a SAT (scanning acoustic tomograph) manufactured by Hitachi, Ltd. The results are shown in FIG. 12.

In the prototype 1, in which the radius of the through hole is 10 microns, separation happened after 2000 thermal cycles. However, no separation was observed in the other prototypes. In the prototype 1, it is assumed that the largest film thickness of a primer layer was larger than those of the other prototypes because the radius of the through hole was small, and excessive primer did not flow into the through hole sufficiently. In the comparative example without the through hole, the largest film thickness of a primer layer is larger than those of any of the prototypes, and separation happened after 1000 thermal cycles.

From the results in FIG. 12, it was confirmed that the through holes have effects to prevent an increase in the film thickness of the primer layer at the edge of the fillet, thereby preventing separation.

Notes regarding the technology explained in the embodiments of the present invention will be given. The dents are provided before soldering the semiconductor chips. When the dents are provided, there is no fillet. Therefore, a guide for providing the dents in the edge of the fillet is predetermined attaching positions of the semiconductor chips. In a plan view of the semiconductor device, the width of the fillet is generally equal to the thickness of the solder layer. Therefore, an adequate position for the dent to be provided is a position away from the predetermined attaching position of the semiconductor chip by a distance obtained by adding a margin to a predetermined height of the solder layer. The margin is about equal to or about twice an average thickness of the primer layer. Where the height of the solder layer is Hs, and the average thickness of the primer layer is Ta, it is preferred that the dent is provided at a position away from the edge of the attaching position of the semiconductor chip by a distance of about (Hs+Ta) to (Hs+2Ta), in a plan view of the semiconductor device.

In a case where the metallic plate is arranged on both sides of the semiconductor chip, the dents only need to be provided in any one of the metallic plates. The one of the metallic plate is located underneath the semiconductor chip after the primer is applied. Immediately after the primer is applied, the excessive primer in a liquid state passes from the side surfaces of the semiconductor chip through the surface of the fillet and moves to the metallic plate below.

In the foregoing embodiments, the metallic plates, onto which the semiconductor chips are soldered, are heat sinks, and surfaces of the metallic plates on one side are exposed from the resin molding. The present invention may be applied to a semiconductor device in which the metallic plates are buried in the resin molding. Typically, the present invention may be applied to a semiconductor device, in which an IC chip and a PLC chip having a number of transistor devices are soldered to a lead frame, and the chips and the lead frame are sealed by the resin molding.

In the embodiments of the present invention, the semiconductor chips are bonded to the metallic plates by the solder layers. The present invention may be applied to a semiconductor device in which an adhesive is used instead of the solder. In the embodiments of the present invention, the fillets of the solder layers were mentioned. However, even in a case where bonding layers are layers other than the solder layers, a side end portion of the bonding layer between the semiconductor chip and the metallic plate is equivalent to the fillet in the foregoing explanation.

It should be noted that, the expression that “the resin molding is in contact with the metallic plate” herein includes a state where the primer is present between the resin molding and the metallic plate. The primer is a coating agent for enhancing bonding between the resin molding and the metallic plate.

The specific embodiments of the present invention have been explained in detail, but are mere examples and do not limit the present invention. The present invention includes the specific embodiments stated above with various modifications and changes, or combinations of the modifications and changes. One of or various combinations of the technical elements explained in the description and the drawings exert technical usability. The technologies shown in the description and the drawings as examples are able to achieve a plurality of objectives simultaneously, and have technical usability only by achieving one of the objectives.

What is claimed is:

1. A semiconductor device comprising:
a metallic plate having a dent;
a bonding layer;
a semiconductor chip fixed to the metallic plate with the bonding layer located between the semiconductor chip and the metallic plate; and
a resin molding that is in contact with the metallic plate and covers the semiconductor chip, wherein
the dent is located next to an edge of a fillet of the bonding layer, in a plan view of the metallic plate.

2. The semiconductor device according to claim 1, further comprising
a primer that is directly applied onto the fillet and the metallic plate from the edge of the fillet through the dent in the metallic plate.

3. The semiconductor device according to claim 1, wherein
the bonding layer is a solder layer.

4. The semiconductor device according to claim 1, wherein
the dent passes though the metallic plate.

5. The semiconductor device according to claim 1, further comprising
a primer that is directly applied onto the metallic plate, wherein
a distance between the edge of the fillet and the dent is twice a thickness of the primer or less.

6. The semiconductor device according to claim 5, wherein
the primer is formed of a thermosetting polyimide resin.

7. The semiconductor device according to claim 6, wherein
an average thickness of the primer is 20 microns or less, and
a distance between the dent and the edge of the fillet is 40 microns or less.

8. The semiconductor device according to claim 7, wherein
a diameter of the dent is twice the average thickness of the primer or more.

9. The semiconductor device according to claim 1, wherein
the dent is provided along an outer edge of the fillet of the bonding layer to surround the fillet in a plan view of the semiconductor device.

10. A manufacturing method for a semiconductor device, comprising:
providing a dent in a metallic plate; and
bonding a semiconductor chip to the metallic plate with a bonding layer after inserting a plug into the dent, the bonding layer located between the semiconductor chip and the metallic plate, wherein
the dent is located next to an edge of a fillet of the bonding layer, in a plan view of the metallic plate.

11. The manufacturing method according to claim 10, further comprising:
pulling off the plug from the dent after bonding the metallic plate to the semiconductor chip; and
directly applying a primer to the fillet and the metallic plate from the edge of the fillet of the bonding layer through the dent.

12. The manufacturing method according to claim 11, further comprising
covering the semiconductor chip with a resin molding after directly applying the primer to the fillet and the metallic plate.

13. The manufacturing method according to claim 12, wherein
the dent is provided at a position away from the semiconductor chip by a distance that is obtained by adding a given distance to a height of the bonding layer, in a plan view of the metallic plate.

14. The manufacturing method according to claim 13, wherein
the given distance is twice a thickness of the primer or less.

15. The manufacturing method according to claim 10, further comprising
positioning the semiconductor chip on the metallic plate by using a part of the plug exposed from the dent, before the semiconductor chip is bonded to the metallic plate.
